(19) United States
(12) Patent Application Publication
(10) Pub. No.: US 2026/0092397 A1
(43) Pub. Date: Apr. 2, 2026

(54) SUBSTRATE PROCESSING APPARATUS

(71) Applicant: JUSUNG ENGINEERING CO., LTD., Gwangju-si, Gyeonggi-do (KR)

(72) Inventors: Do Hyung KIM, Hanam-si, Gyeonggi-do (KR); Chul Joo HWANG, Seongnam-si, Gyeonggi-do (KR)

(21) Appl. No.: 19/112,240

(22) PCT Filed: Sep. 25, 2023
(86) PCT No.: PCT/KR2023/014609

§ 371 Date: Mar. 14, 2025

(30) Foreign Application Priority Data
Oct. 20, 2022 (KR) 10-2022-0135333

(51) Int. Cl. C30B 25/12; C30B 25/08; C30B 25/10

(52) U.S. Cl. CPC C30B 25/12; C30B 25/08; C30B 25/105

(57) ABSTRACT

A substrate processing apparatus according to an example embodiment includes a chamber having a sidewall, a susceptor having an inclined side surface and mounting a substrate inside the chamber, an upper dome covering an upper surface of the chamber and formed of a dielectric material, a lower dome covering a lower surface of the chamber and formed of a dielectric material, and a liner disposed inside the chamber and disposed between the upper dome and the lower dome. The liner may include an inclined portion having an inclined inner side surface opposing the included side surface of the susceptor.

### TECHNICAL FIELD

The present disclosure relates to a substrate processing apparatus, and more particularly, to an epitaxial plasma enhanced chemical vapor deposition apparatus for rapidly heating a substrate at high temperature using a lamp heater to deposit a thin film.

### BACKGROUND

In semiconductor fabrication, a single-crystalline silicon thin film having the same crystal structure as a single-crystalline silicon substrate is deposited on the substrate. When the single-crystalline silicon thin film is grown, an inorganic insulating material such as silicon oxide is deposited and patterned to form a single-crystalline region only in a silicon-exposed portion of a semiconductor surface, which is referred to as selective epitaxial growth (SEG).

In addition, in manufacturing of a thin-film solar cell on a large-area substrate, a P-type layer receiving sunlight, an I-type layer forming an electron-hole pair, and an N-type layer serving as an opposite electrode of the P-type layer are the basic elements. Similarly, a liquid crystal display (LCD) device is based on an array element and a color filter element, respectively formed on an array and a color filter substrate.

A photolithography process is required to be performed several times to fabricate a thin film element for a solar cell and a liquid crystal display device. Such a photolithography process includes a thin film deposition process, a photosensitive layer coating process, an exposure and development process, and an etching process. In addition, such a photolithography process accompanies various processes such as a cleaning process, an attaching process, a cutting process, or the like.

Plasma-enhanced chemical vapor deposition (hereinafter referred to as “PECVD”) is a process by which a thin film is formed while reaction gas is excited into a plasma state inside a chamber by applying a radio-frequency (RF) high voltage to an antenna or an electrode.

Recently, to prevent particles or byproducts generated during a deposition process using PECVD from adhering to an inner wall of a chamber, the inner wall is designed with quartz, and an upper dome and a lower dome are designed with quartz in an upper portion and a lower portion of the chamber.

In a deposition process using such PECVD, a pressure inside a chamber is maintained at several mTorr and is maintained in an ultra-high vacuum state of 10E-9 Torr in a base vacuum state to significantly decrease the number of particles or byproducts generated during the deposition process and to reduce a time for the deposition process, resulting in an advantage for improving production yield.

Such PECVD has an issue in which processing gas injected into an upper space between an upper dome and a susceptor may be introduced into a lower space in a lower portion of the susceptor to cause particles or byproducts.

### SUMMARY

An aspect of the present disclosure is to prevent processing gas, injected into an upper space between an upper dome and a susceptor, from being introduced into a lower space of a lower portion of the susceptor by using a structure of a liner disposed between the upper dome and a lower dome and a shape of the susceptor.

A substrate processing apparatus according to an example embodiment includes a chamber having a sidewall, a susceptor having an inclined side surface and mounting a substrate inside the chamber, an upper dome covering an upper surface of the chamber and formed of a dielectric material, a lower dome covering a lower surface of the chamber and formed of a dielectric material, and a liner disposed inside the chamber and disposed between the upper dome and the lower dome. The liner may include an inclined portion having an inclined inner side surface opposing the inclined side surface of the susceptor.

In an example embodiment, a first angle of inclination of the inclined side surface of the susceptor may be the same as a second angle of inclination of the inclined portion of the liner.

In an example embodiment, each of the first angle of inclination and the second angle of inclination may be 70 degrees.

In an example embodiment, the liner may include an upper liner, having a first inner diameter and disposed adjacent to the upper dome, and a lower liner continuously connected to the upper liner and comprising the inclined portion having an increasing inner diameter. The lower liner may include a first opening, disposed adjacent to a lower surface of the upper liner to exhaust gas, and a second opening disposed on the other side, opposing the first opening, to provide a path of a substrate.

In an example embodiment, the susceptor may have a thickness greater than a height of the first opening or a height of the second opening.

In an example embodiment, a distance between the inclined portion of the lower liner and the inclined side surface of the susceptor may be 1 millimeter (mm) to 3 mm when the susceptor is disposed in an up-position.

In an example embodiment, a distance between the inclined portion of the lower liner and the inclined side surface of the susceptor may be 7 mm to 13 mm when the susceptor is disposed in a down-position.

In an example embodiment, the liner may further include a connection portion curved between the upper liner and the lower liner.

In an example embodiment, the connection portion may have a diameter greater than a diameter of an upper surface of the susceptor and smaller than a diameter of a lower surface of the susceptor.

In an example embodiment, the susceptor may include a curved portion, curved on an upper surface of the susceptor, and the inclined side surface continuously connected to the curved portion.

In an example embodiment, the susceptor may include a curved portion, curved on an upper surface of the susceptor, and the inclined side surface continuously connected to the curved portion, and the curved portion of the susceptor may face the connection portion of the liner.

In an example embodiment, a vertical distance between the curved portion of the susceptor and the connection portion of the liner may be 4 mm to 7 mm.

In an example embodiment, the susceptor may be formed of ceramic or graphite and may have a thickness of 30 mm or more.

In an example embodiment, an upper space, defined by the susceptor and the upper dome, may be smaller than a lower space, defined by the lower dome and the susceptor, when the susceptor is disposed in a process position.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a conceptual diagram illustrating a home position in a plasma enhanced chemical vapor deposition apparatus according to an embodiment of the present disclosure.

FIG. 2 is a conceptual diagram illustrating an up-position in the plasma enhanced chemical vapor deposition apparatus of FIG. 1.

FIG. 3 is a conceptual diagram, taken in another direction, illustrating the plasma enhanced chemical vapor deposition apparatus of FIG. 1.

FIG. 4 is a cutaway perspective view illustrating an upper liner, a lower liner, and a lower dome of the plasma enhanced chemical vapor deposition apparatus of FIG. 1.

FIG. 5 is a conceptual diagram illustrating a plasma enhanced chemical vapor deposition apparatus according to another embodiment of the present disclosure.

### DETAILED DESCRIPTION

Conventionally, a high process temperature of about 900 degrees Celsius is required to grow a silicon-germanium single-crystalline or silicon single-crystalline layer on a substrate. In semiconductor fabrication using such a selective epitaxial growth, there is an advantage for easily fabricating a semiconductor device having a three-dimensional structure such as a FIN-FET which is difficult to be fabricated using a conventional flat plate technology.

A chemical vapor deposition apparatus, including an upper dome and a lower dome, uses a liner to prevent unwanted deposition of a thin film on an inner wall of a chamber. The liner may be periodically replaced or cleaned.

A chemical vapor deposition apparatus according to an example embodiment, including an upper dome and a lower dome, may inject processing gas into an upper space defined by the upper dome and a susceptor, and may exhaust the processing gas through an opening of the liner connected to the upper space. When the processing gas supplied to the upper space is introduced into the lower space through the lower dome and the susceptor, an abnormal thin film may be deposited on the lower dome and the liner.

The liner according to the present disclosure may include an upper liner having a constant inner diameter, a lower liner continuously connected to the upper liner and having an increasing inner diameter with a constant angle of inclination, and a connection portion having a curve between the upper liner and the lower liner.

The susceptor according to the present disclosure may have a thickness of 30 mm or more, and a side surface of the susceptor may have an angle of inclination. Additionally, the liner may have an inclined portion to maintain a constant distance from the inclined side surface of the susceptor.

When the susceptor is in a process position (or an up-position) to process a substrate, the susceptor may be lifted to the connection portion of the liner. A distance (or a gap) between the lower liner and the inclined side surface of the susceptor may be maintained at a level of 2 mm. Such a narrow gap may provide low conductance to inhibit the processing gas in the upper space from moving into the lower space.

A first opening for exhaustion of the processing gas and a second opening for entry and exit of the substrate may be formed in the lower liner, and may be in contact with the connection portion. Accordingly, when the susceptor is in the process position, the inclined side surface of the susceptor may be disposed to oppose the first opening and the second opening, so that the first opening and the second opening may be substantially closed. However, the connection portion may define a space on an upper side surface of the susceptor, and the connection portion and the first opening may provide a path for exhaustion of the processing gas.

The susceptor may have a sufficient thickness, and may have a greater height than the first opening. In the process position, an upper surface of the susceptor may be set to be substantially the same as an upper surface of the first opening, and a lower surface of the susceptor may be set to be substantially lower than a lower surface of the first opening. The gap between the inclined side surface of the susceptor and the lower liner may be maintained at a level of 2 mm. Accordingly, the processing gas introduced in a direction of the first opening may not be introduced into the lower space due to low conductance.

The susceptor according to the present disclosure may have a thickness sufficient to cover the first opening and an inclined side surface, and may inhibit the processing gas injected into the upper space from entering the lower space. Accordingly, the lower space may inhibit generation of an abnormal thin film and particles. In addition, the inclined side surface of the susceptor may inhibit a light of an infrared lamp from entering the upper space to efficiently heat the susceptor.

According to the present disclosure, the susceptor may be rotated to achieve process uniformity.

According to the present disclosure, by supplying purge gas to the lower dome and supplying processing gas to an upper space between the upper dome and the susceptor, the processing gas may be prevented from flowing into the lower dome to inhibit deposition of an abnormal thin film on the lower dome.

According to the present disclosure, when the susceptor is in the process position, the upper space may be smaller than the lower space. To this end, a height of the lower liner may be greater than the height of the upper liner. As the upper space decreases, a deposition rate may increase.

In the present disclosure, the lower liner may have an inclined surface to inject purge gas, supplied from the lower dome, in a direction toward the upper dome and to install more lamp heaters. The gap between the susceptor and the lower liner may be maintained to be narrow, so the purge gas supplied from the lower dome may be injected toward the upper dome to cause a pressure difference. Due to the narrow gap between the susceptor and the lower liner, the processing gas injected into the upper space may stay only inside the upper space to prevent contamination of the lower space.

In the present disclosure, an antenna for inductively coupled plasma may be disposed to be spaced apart from an upper dome, conducting wires constituting the antenna may be in the form of strip lines, and the strip lines may be vertically aligned in a width direction. Accordingly, infrared light incident in a direction of a lower dome may be minimally incident on the antenna. As a result, the antenna may suppress heating by the infrared light, and infrared light reflected from an electromagnetic wave shield housing may significantly reduce a shadow.

In the present disclosure, an electromagnetic wave shield housing surrounding an antenna and shielding an electromagnetic wave may be plated by gold plating, so that infrared light may be reflected and be then re-incident on the substrate. In addition, the electromagnetic wave shield housing may have a cylindrical shape, rather than a dome shape, to reduce re-incident heating of the antenna caused by reflection of the infrared light.

In the present disclosure, a lamp heater disposed below the lower dome may be a ring-shaped lamp heater and may be provided as a plurality of lamp heaters. Ring-shaped lamp heaters may be grouped together to independently control power to uniformly heat a substrate.

In the present disclosure, a turbomolecular pump (TMP) connected to an exhaust portion of a chamber may allow base vacuum to be maintained inside the chamber, and may generate stable plasma at a pressure of several Torr or less even during a process.

Plasma-assisted chemical vapor deposition according to the present disclosure may reduce performance degradation caused by infrared heating of an inductively coupled plasma antenna disposed on an upper dome and may provide infrared light, reflected from an electromagnetic wave shield housing, back to a substrate to form a uniform thin film on the substrate at high speed.

When a lamp heater is applied for a process temperature of about 900 degrees Celsius, an antenna for generating inductively coupled plasma in a process container may be heated by the lamp heater to increase a temperature, and thus, a resistance value may be increased. Accordingly, the antenna may not efficiently generate inductively coupled plasma due to energy consumption caused by ohmic heating. In addition, the antenna may form a shadow for infrared light, reflected from an electromagnetic wave shield housing, to provide temperature non-uniformity to the substrate. To achieve process stability, the electromagnetic wave shield housing may be heated to shield electromagnetic waves while maintaining the antenna at a constant temperature.

In addition, the electromagnetic wave shield housing disposed to surround the antenna may reflect a portion of the infrared light emitted from the lamp heater, and the remaining portion of the infrared light may be absorbed and heated in the electromagnetic wave shield housing to reduce reliability. Spatially non-uniform temperature distribution in the electromagnetic wave shield housing may provide spatially non-uniform blackbody radiation. Accordingly, the electromagnetic wave shield housing may employ an additional resistive heater to perform heating to a uniform temperature and may provide spatially uniform black body radiation. The electromagnetic wave shield housing may be heated to 200 degrees Celsius to 600 degrees Celsius, and heat loss may increase when the electromagnetic wave shield housing is brought into direct thermal contact with a chamber. Accordingly, the electromagnetic wave shield housing may be thermally insulated from the chamber to significantly reduce the heat loss. For example, an insulating spacer may be disposed between the electromagnetic wave shield housing and the chamber to reduce the heat loss of the electromagnetic wave shield housing. The electromagnetic wave shield housing may be electrically grounded through an additional conductive line. The insulating spacer may have a ring shape, and may be formed of a ceramic material. The insulating spacer may be formed of a porous ceramic material.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

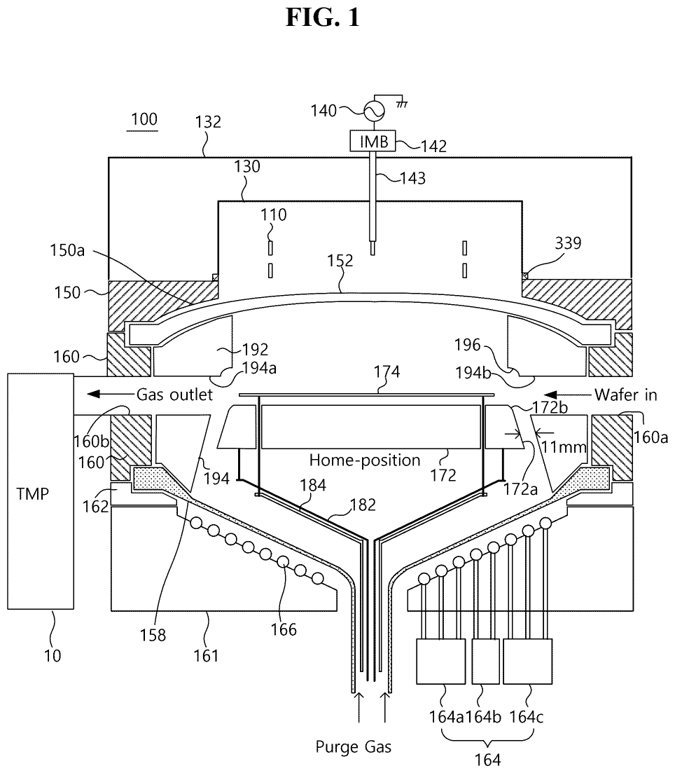

FIG. 1 is a conceptual diagram illustrating a home position in a plasma enhanced chemical vapor deposition apparatus according to an embodiment of the present disclosure.

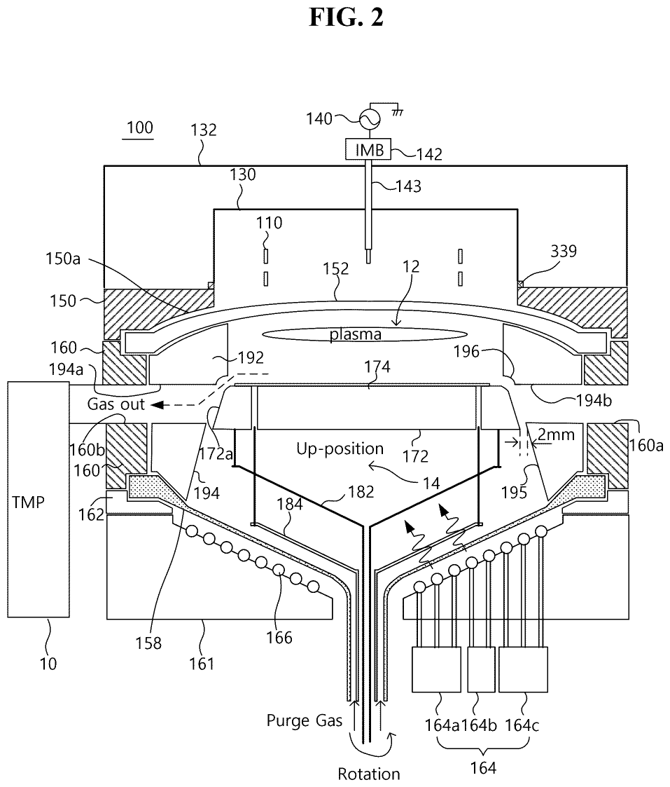

FIG. 2 is a conceptual diagram illustrating an up-position in the plasma enhanced chemical vapor deposition apparatus of FIG. 1.

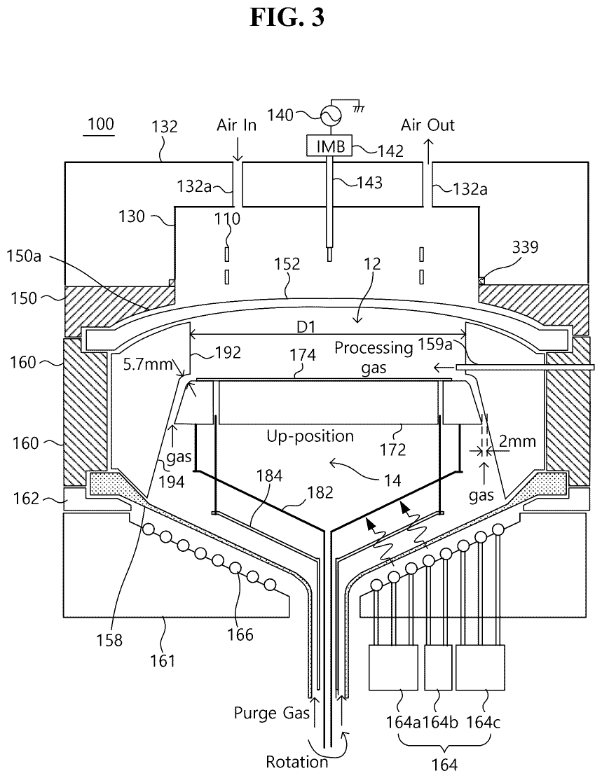

FIG. 3 is a conceptual diagram, taken in another direction, illustrating the plasma enhanced chemical vapor deposition apparatus of FIG. 1.

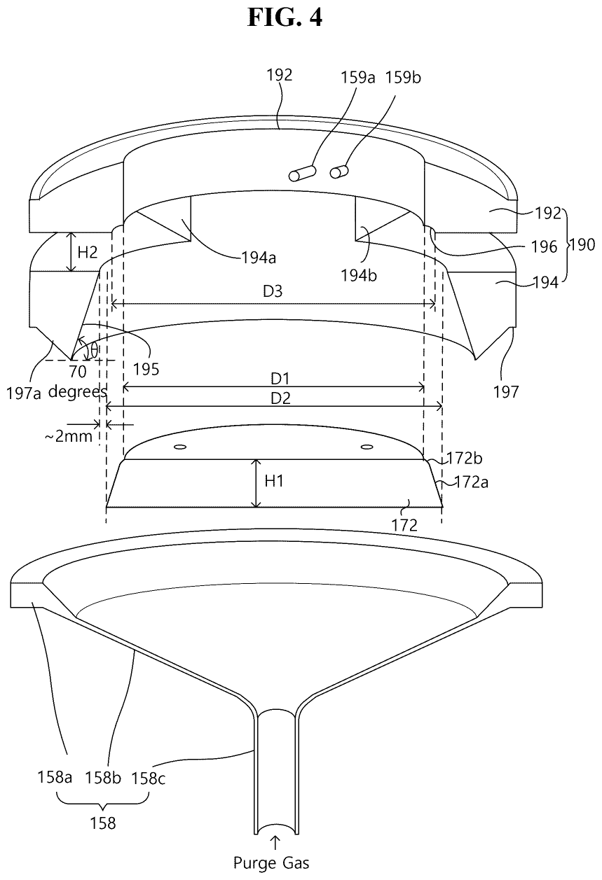

FIG. 4 is a cutaway perspective view illustrating an upper liner, a lower liner, and a lower dome of the plasma enhanced chemical vapor deposition apparatus of FIG. 1.

Referring to FIGS. 1 to 4, a plasma enhanced chemical vapor deposition apparatus 100 may include a chamber 160 having a sidewall, a susceptor 172 having an inclined side surface and mounting a substrate inside the chamber 160, an upper dome 152 covering an upper surface of the chamber 160 and formed of a dielectric material, a lower dome 158 covering a lower surface of the chamber 160 and formed of a dielectric material, and a liner 190 disposed inside the chamber 160 and disposed between the upper dome 152 and the lower dome 158. The liner 190 may include an inclined portion 195 having an inclined inner side surface opposing the inclined side surface 172a of the susceptor 172.

The chamber 160 may be formed of a conductor, and may have a cylindrical internal space and a rectangular external space. The chamber 160 may be cooled by cooling water. The chamber 160, the upper dome 152, and the lower dome 158 may be coupled to each other to provide an enclosed space. The chamber 160 may include a substrate entrance 160a, formed on a side surface of the chamber 160, and an exhaust port 160b formed on a side surface facing the substrate entrance 160a. The exhaust port 160b may be connected to a high-vacuum pump 10. The high-vacuum pump 10 may be a turbomolecular pump. The high-vacuum pump may be maintained at low base pressure, and may be maintained at pressure of several Torr or less even during a process. An upper surface of the exhaust port 160b may be disposed on the same level as or higher than an upper surface of the substrate entrance 160a.

For example, when the upper surface of the exhaust port 160b is disposed on the same level as the upper surface of the substrate entrance 160a, an upper surface of the susceptor 172 may be changed to the same position as upper surfaces of the exhaust port 160b and the substrate entrance 160a during a process. Thus, symmetry inside the chamber 160 may be improved, and a flow of processing gas may be improved to provide uniform thin film deposition.

The susceptor 172 may mount the substrate 174 when the substrate 174 is introduced through the substrate entrance 160a formed on the side surface of the chamber 160. The susceptor 172 may have a disc shape, and may have a thickness of 30 mm or more. The susceptor 172 may have a thickness H1 of, in detail, 40 mm or more. The susceptor 172 may include a curved portion 172b, curved on an upper surface of the susceptor 172, and an inclined side surface 172a continuously connected to the curved portion. A first angle of inclination of the inclined side surface 172a of the susceptor 172 may be 70 degrees. The thickness H1 of the susceptor 172 may be greater than a height H2 of the first opening or a height H2 of the second opening.

The susceptor 172 may have the same plate shape as the substrate 174, and may be formed of ceramic or graphite having improved thermal conductivity. The susceptor 172 may be heated by infrared light incident from a lower portion thereof, and the substrate 174 may be heated by heat transfer. During a process, an upper surface of the susceptor 172 may be substantially the same as upper surfaces of the exhaust port 160b and the substrate entrance 160a. The susceptor 172 may be rotated to improve azimuthal symmetry.

A first lifter 184 may extend along a central axis of the lower dome 158, and may include a first lifter body having a tripod shape and a first lift pin. The first lifter 184 and a second lifter 182 may have a coaxial structure. When the substrate 174 is transferred into the chamber 160, the first lifter 184 may be lifted from a down-position or a home position to support the substrate 174. Then, the first lifter 184 may be lowered to place the substrate 174 on the susceptor 172. A material of the first lifter 184 may be quartz or a metal. The first lifter 184 may be vertically moved by a driving shaft.

The second lifter 182 may extend along the central axis of the lower dome 158, and may include a second lifter body having a tripod shape and a second lift pin. The second lifter 182 may lift the susceptor 172, on which the substrate 174 is mounted, from a home position (or a down-position) to a process position (or an up-position). At the process position, the upper surface of the susceptor 172 may be disposed in substantially the same plane as an upper surface of a second opening 194b for introducing the substrate 174 in the upper liner 190. In addition, at the process position, the upper surface of the susceptor 172 may be disposed in substantially the same plane as an upper surface of a first opening 194a for exhausting gas in the liner 190. Accordingly, the inclined side surface 172a of the susceptor 172 may be disposed to close the first opening 194a and the second opening 194b. A material of the second lifter 182 may be quartz or a metal. The second lifter 182 may be vertically moved by a driving shaft. The second lifter 182 may be rotated to rotate the susceptor 172.

The upper dome 152 may be quartz or sapphire as a dielectric material. The upper dome 152 may be inserted into and coupled to a raised spot formed on the upper surface of the chamber 160. In the upper dome 152, a coupling portion coupled to the chamber 160 to provide vacuum sealing may have a washer shape. The upper dome 152 may have an arc shape or an elliptical shape. The upper dome 152 may allow infrared light, incident from the lower portion, to pass therethrough. Infrared light, reflected from the electromagnetic wave shield housing 130, may pass through the upper dome 152 to be re-incident on the substrate 174.

The lower dome 158 may be quartz or sapphire as a dielectric material. The lower dome 158 may include a funnel-shaped lower dome body 158b, a washer-shaped coupling portion 158a coupled to a raised spot formed on the lower surface of the chamber 160, and a cylindrical pipe 158c having a cylindrical shape and connected to the center of the lower dome body 158b. The lower dome 158 may be inserted into and coupled to a raised spot formed on the lower surface of the chamber 160. A coupling portion 158a of the lower dome 158, coupled to the chamber to provide vacuum sealing, may have a washer shape. A driving shaft of the first lifter 184 and a driving shaft of the second lifter 182 may be disposed to be inserted into the cylindrical pipe 158c. Purge gas, supplied through the lower dome 158, may be supplied through a flow path. The flow path may be a cylindrical pipe 158c. The purge gas may be inert gas such as argon or nitrogen. The purge gas may inhibit the processing gas from being injected into the lower space below the susceptor 172.

The liner 190 may be disposed inside the chamber 160, and may be disposed between the upper dome 152 and the lower dome 158. The liner 190 may include an inclined portion 195 having an inclined inner side surface. A second angle of inclination of the inclined portion 195 of the liner 190 may be equal to the first angle of inclination of the inclined side surface 172a of the susceptor 172. Each of the first angle of inclination and the second angle of inclination may be 70 degrees. When the first inclination angle and the second inclination angle are the same, the inclined side surface 172a of the susceptor 170 and the inclined portion 195 of the liner 190 may be maintained at a constant distance. When the susceptor 170 is in the process position, the inclined side surface 172a of the susceptor 172 and the inclined portion 195 of the liner 190 may be maintained at a minimum gap of 2 mm.

The liner 190 may include an upper liner 192, having a first inner diameter D1 and disposed adjacent to the upper dome 152, and a lower liner 194 continuously connected to the upper liner 192 and including the inclined portion 195 having an increasing inner diameter. The lower liner 194 may include a first opening 194a, disposed adjacent to a lower surface of the upper liner 192 to exhaust gas, and a second opening 194b disposed to provide a path of a substrate to the other side facing the first opening 194a. The liner 190 may further include a curved connection portion 196 between the upper liner and the lower liner. The upper liner 192 and the lower liner 194 may be formed to be integrated with each other. The liner 190 may include an upper liner 192 having a constant inner diameter, a connection portion 196 having a curvature at the upper liner 192 and having an increasing diameter, and a lower liner 194 having a constant angle of inclination in the bonding portion.

When the susceptor 172 is in the down-position, a gap between the inclined portion 195 of the lower liner 194 and the inclined side surface 172a of the susceptor 170 may be 7 mm to 13 mm, in detail, approximately 11 mm.

When the susceptor 172 is in in the up-position, a gap between the inclined side surface 172a of the susceptor 172 and the inclined portion 195 of the liner 190 may be 1 mm to 3 mm, in detail, approximately 2 mm. Such a narrow gap may reduce a cross-sectional area, allowing fluid to flow therethrough, to provide low conductance. A thickness of the susceptor 172 of tens of millimeters or more may provide lower conductance to the fluid.

When the susceptor 172 is in the up-position, a vertical distance between the curved portion 172b of the susceptor 172 and the connection portion 196 of the liner 190 may be 4 mm to 7 mm, in detail, 5.7 mm. An outer diameter of the upper surface of the susceptor 172 may be substantially equal to the inner diameter D1 of the upper liner 192, or may be several millimeters larger than the inner diameter D1 of the upper liner 192. When the susceptor 172 is lifted such that the upper surface of the susceptor 172 matches the upper surface of the first opening, the connection portion 196 may provide an exhaust path allowing the processing gas to be discharged to the first opening.

The liner 190 may be a transparent or opaque dielectric material. The liner 190 may be quartz, alumina, sapphire, or aluminum nitride. The liner 190 may be selected from a material inhibiting the deposition of abnormal thin films. When the liner 190 is contaminated, it may be disassembled and cleaned.

The upper liner 192 may have an overall ring shape, and the upper surface of the upper liner 192 may be a curved surface having a shape of the upper dome 152. The outer upper surface of the upper liner 192 may have a flat portion. An inner diameter of the upper liner 192 may be D1.

The upper liner 192 may include at least one processing gas supply part 159a and 159b supplying processing gas through a side surface of the upper liner. The processing gas supply parts 159a and 159b may protrude from the inner surface of the upper liner 192. For example, the processing gas supply part may include a first processing gas supply part 159a, supplying first processing gas such as SiH4, and a second processing gas supply part 159b supplying second processing gas.

The first processing gas supply part 159a may protrude more from the side surface of the upper liner 192 to expose a large amount of the first processing gas, such as SiH4, to plasma. On the other hand, the second processing gas supply part 159b may protrude less from the side surface of the upper liner 192 to expose a small amount of the second processing gas, such as hydrogen gas H2, to plasma. Since the purge gas is introduced into the upper space 12 of the chamber 160 from the lower dome 158, it may be uniformly supplied around a circumference to have a spatially uniform pressure distribution.

The connection portion 196 may have a depressed structure with a curvature on a lower inner surface of the upper liner 192. The connection portion 196 may have a depth and a width of several millimeters. A diameter D3 of the connection portion 196 may be greater than a diameter of the upper surface of the susceptor 172 and smaller than the diameter D2 of the lower surface of the susceptor 172. Accordingly, the curved portion 172b of the susceptor 172 may face the connection portion 196 at a predetermined gap.

The lower liner 194 may be disposed inside the chamber and have a cylindrical shape surrounding an inner circumferential surface of an upper edge of the lower dome 158. The lower liner 194 may include an inclined lower outer surface 197a coupling to the lower dome 158 and an inclined portion 195 inclined on the inner surface. The inclined lower outer surface 197a may have a flat portion 197 on an outer side.

The lower liner 194 may be transparent or opaque quartz. For example, the lower liner may have an inner circumferential surface facing a space of the lower dome 158, and the inner circumferential surface of the lower liner 194 may have a slope along which a thickness increases from a lower portion to an upper portion of the chamber 160 in a vertical direction. The second angle of inclination θ of the inclined portion may be about 70 degrees. The inclined portion 195 may expose the lamp heater 166 to provide more uniform heating, and may scatter incident infrared light to suppress heating of the chamber 160.

Inert gas (or purge gas), such as argon, nitrogen, or the like, may be injected between the susceptor 172 and the lower liner 194 to inhibit the processing gas from being injected into the lower space.

The lower liner 194 may have a first opening 194a, formed on an inner side surface adjacent to the upper liner 192 to exhaust gas, and a second opening 194b formed on the other side, facing the first opening 194a, to provide a path for the substrate. The first opening 194a and the second opening 194b may be formed in the inclined portion 195. The first opening 194a may be aligned with the exhaust portion, and the second opening 194b may be aligned with a substrate entrance. When the susceptor 172 is disposed in an up-position, the first opening 194a and the second opening 194b may be substantially closed by the susceptor 172 to inhibit the processing gas of the upper space 12 from moving to the lower space 14 defined by the susceptor 172 and the lower dome 158. The first opening 194a, the connection portion 196, and the curved portion 172b of the susceptor 172 may provide a path through which the processing gas may flow.

An insulation portion 162 may be disposed between the lower surface of the chamber 160 and a reflector 161 and may have a ring shape. The insulation portion 162 may reduce heat transfer from the heated reflector 161 to the chamber 160. The insulation portion 162 may be formed of a ceramic material. An upper surface of the insulation portion 162 may be provided with a raised spot. The raised spot of the insulation portion 162 and the raised spot of the lower surface of the chamber 160 may accommodate the washer-shaped coupling portion 158a of the lower dome 158 and may vacuum-seal the washer-shaped coupling portion 158a of the lower dome 158.

A concentric lamp heater 166 may include a plurality of concentric ring-shaped lamp heaters, and may be connected to a power supply 164. The concentric ring-shaped lamp heaters may be arranged at regular intervals along the inclined surface of the lower dome 158, and may be divided into three groups to independently receive power. The concentric ring-shaped lamp heater 166 may be inserted into a ring-shaped groove, formed on an inclined surface of the reflector 161, to be aligned. For example, the concentric ring-shaped lamp heater 166 may be a halogen lamp heater, and eight concentric ring-shaped lamp heaters 166 may be provided. Lower three lamp heaters may constitute a first group, intermediate two lamp heaters may constitute a second group, and upper three lamp heaters may constitute a third group. The first group may be connected to a first power supply 164a, the second group may be connected to a second power supply 164b, and the third group may be connected to a third power supply 164c. The first, second, and third power supplies 164a, 164b, and 164c may be independently controlled to uniformly heat the substrate.

The reflector 161 may support a lower surface of the insulation portion 162, and may mount the lamp heater. An inclined surface, on which the lamp heater 166 is mounted, may have a conic shape to be maintained at a predetermined gap from the inclined surface of the lower dome 158. The reflector 161 may be formed of a conductive material, and may be cooled by cooling water.

A clamp 150 may be disposed to contact the upper surface of the chamber 160 and to cover an edge of the upper dome 152. The clamp 150 may be formed of a conductive material, and may be cooled by cooling water. A lower surface of the clamp 150 may be provided with a raised spot to be coupled to the washer-shaped coupling portion of the upper dome 152, and may include a curved portion 150a to cover a portion of the curved portion of the upper dome 152. The curved portion 150a of the clamp 150 may be plated with gold to reflect infrared light. An inner diameter of the clamp 150 may be substantially the same as or greater than an inner diameter D1 of the upper liner. In addition, the inner diameter of the clamp 150 may be the same as a diameter of the electromagnetic wave shield housing 130.

An antenna 110 may be disposed on the upper dome 152 to generate inductively-coupled plasma in the upper space 12. A radio-frequency (RF) power supply 140 may supply RF power to the antenna 110 through an impedance matching box (IMB) 142 and a power supply line 143.

The electromagnetic wave shield housing 130 may be disposed to surround the antenna 110. The insulation spacer 339 may be thermally insulated from the electromagnetic wave shield housing 130 and the upper surface of the chamber 160. A cooling housing 132 may be disposed to surround the electromagnetic wave shield housing 130 while being spaced apart from the electromagnetic wave shield housing 130. The cooling housing 132 may have a flow path (132a) therein and may be cooled by a refrigerant.

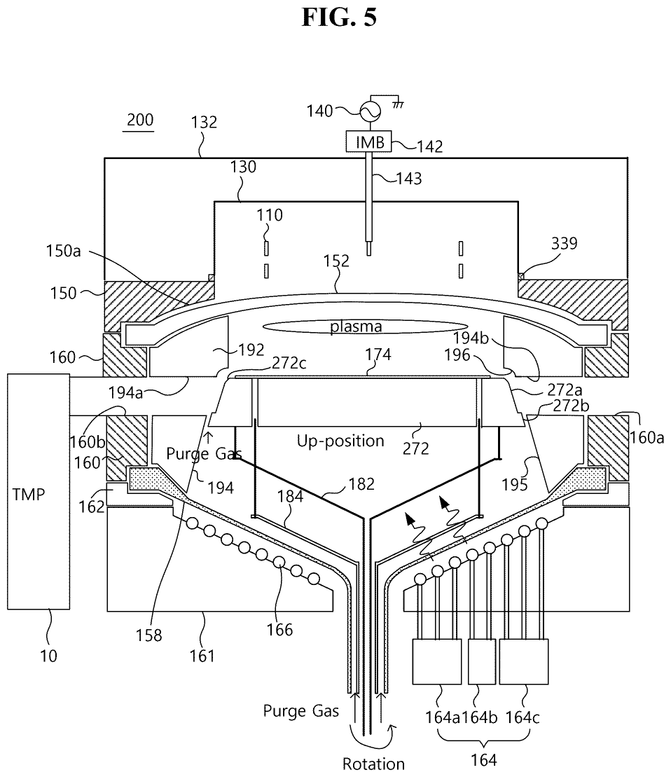

FIG. 5 is a conceptual diagram illustrating a plasma enhanced chemical vapor deposition apparatus according to another embodiment of the present disclosure.

Referring to FIG. 5, a plasma chemical vapor deposition apparatus 200 according to an example embodiment may include a chamber 160 having a side wall, a susceptor 272 having inclined side surfaces 272a and 272b and mounting a substrate within the chamber 160, an upper dome 152 covering an upper surface of the chamber 160 and formed of a dielectric material, a lower dome 158 covering a lower surface of the chamber 160 and formed of a dielectric material, and a liner 190 disposed inside the chamber 160 and disposed between the upper dome 152 and the lower dome 158. The liner 190 may include an inclined portion 195 having an inclined inner side surface facing the inclined side surfaces 272a and 272b of the susceptor 272.

The susceptor 272 may include a curved portion 272c, curved on the upper surface of the susceptor, and the inclined side surfaces 272a and 272b continuously connected to the curved portion 272c. The inclined side surface may include at least one of a first inclined surface 272a and a second inclined surface 272b. The first inclined surface 272a may be discontinuously connected to the second inclined surface 272b. The second inclined surface 272b may narrow a gap between a lower liner 194 and the first inclined surface 272a, and may provide a space sufficient to discharge processing gas to a first opening while controlling a direction of flow of the processing gas.

As set forth above, in a substrate processing apparatus according to example embodiments, processing gas introduced into a lower space may be significantly reduced, so that generation of foreign substances and byproducts may be significantly reduced to stably perform plasma enhanced chemical vapor deposition.

Although the present disclosure and its advantages have been described in detail, it should be understood that various changes, substitutions and alterations can be made herein without departing from the spirit and scope of the disclosure as defined by the following claims.

What is claimed is:

1. A substrate processing apparatus comprising:
a chamber having a sidewall;
a susceptor having an inclined side surface and mounting a substrate inside the chamber;
an upper dome covering an upper surface of the chamber and formed of a dielectric material;
a lower dome covering a lower surface of the chamber and formed of a dielectric material; and
a liner disposed inside the chamber and disposed between the upper dome and the lower dome,
wherein
the liner comprises an inclined portion having an inclined inner side surface opposing the inclined side surface of the susceptor.

2. The substrate processing apparatus as set forth in claim 1, wherein
a first angle of inclination of the inclined side surface of the susceptor is the same as a second angle of inclination of the inclined portion of the liner.

3. The substrate processing apparatus as set forth in claim 2, wherein
each of the first angle of inclination and the second angle of inclination is 70 degrees.

4. The substrate processing apparatus as set forth in claim 1, wherein
the liner comprises:
an upper liner having a first inner diameter and disposed adjacent to the upper dome; and
a lower liner continuously connected to the upper liner and comprising the inclined portion having an increasing inner diameter, and
the lower liner comprises a first opening, disposed adjacent to a lower surface of the upper liner to exhaust gas, and a second opening disposed on the other side, opposing the first opening, to provide a path of the substrate.

5. The substrate processing apparatus as set forth in claim 4, wherein
the susceptor has a thickness greater than a height of the first opening or a height of the second opening.

6. The substrate processing apparatus as set forth in claim 4, wherein
a distance between the inclined portion of the lower liner and the inclined side surface of the susceptor is 1 millimeter (mm) to 3 mm when the susceptor is disposed in an up-position.

7. The substrate processing apparatus as set forth in claim 4, wherein
a distance between the inclined portion of the lower liner and the inclined side surface of the susceptor is 7 mm to 13 mm when the susceptor is disposed in a down-position.

8. The substrate processing apparatus as set forth in claim 4, wherein
the liner further comprises a connection portion curved between the upper liner and the lower liner.

9. The substrate processing apparatus as set forth in claim 8, wherein
the connection portion has a diameter greater than a diameter of an upper surface of the susceptor and smaller than a diameter of a lower surface of the susceptor.

10. The substrate processing apparatus as set forth in claim 1, wherein
the susceptor comprises a curved portion, curved on an upper surface of the susceptor, and the inclined side surface continuously connected to the curved portion.

11. The substrate processing apparatus as set forth in claim 8, wherein
the susceptor comprises a curved portion, curved on an upper surface of the susceptor, and the inclined side surface continuously connected to the curved portion, and
the curved portion of the susceptor faces the connection portion of the liner.

12. The substrate processing apparatus as set forth in claim 11, wherein
a vertical distance between the curved portion of the susceptor and the connection portion of the liner is 4 mm to 7 mm.

13. The substrate processing apparatus as set forth in claim 1, wherein
the susceptor is formed of ceramic or graphite, and
the susceptor has a thickness of 30 mm or more.

14. The substrate processing apparatus as set forth in claim 1, wherein
an upper space, defined by the susceptor and the upper dome, is smaller than a lower space, defined by the lower dome and the susceptor, when the susceptor is disposed in a process position.
